(19) United States
(12) Patent Application Publication
(10) Pub. No.: US 2013/0240973 A1
(43) Pub. Date: Sep. 19, 2013

(54) NON-VOLATILE SEMICONDUCTOR MEMORY DEVICE AND METHOD OF MANUFACTURING THE SAME

(71) Applicant: KABUSHIKI KAISHA TOSHIBA, Tokyo (JP)

(72) Inventor: Koichi MATSUNO, Mie-ken (JP)

(73) Assignee: Kabushiki Kaisha Toshiba, Tokyo (JP)

(21) Appl. No.: 13/792,799

(22) Filed: Mar. 11, 2013

(30) Foreign Application Priority Data
Mar. 13, 2012 (JP) 2012-055954

(51) Int. Cl. H01L 29/788; H01L 29/66

(52) U.S. Cl. CPC H01L 29/788; H01L 29/66825
USPC 257/316; 438/257

(57) ABSTRACT

A method of manufacturing a non-volatile semiconductor memory device, comprising the steps of, forming a plurality of element regions and an element isolation region, forming a plurality of memory cell gate electrodes and two selection gate electrodes, etching the first insulating film in such a manner that the first insulating film remains at least under the selection gate electrodes, forming a second insulating film on the selection gate electrodes and under the selection gate electrodes in the element isolation region, the second insulating film having an etching rate in a first etching solution lower than that of the first insulating film, forming a third insulating film on the memory cell gate electrodes in such a manner that air gaps are formed between the memory cell gate electrodes, and forming a contact electrode.

### CROSS-REFERENCE TO RELATED APPLICATION

This application is based upon and claims the benefit of priority from the prior Japanese Patent Application No. 2012-055954, filed Mar. 13, 2012, the entire contents of which are incorporated herein by reference.

### FIELD

An embodiment of the present invention relates to a non-volatile semiconductor memory device and a method of manufacturing the same, and specifically relates to a non-volatile semiconductor memory device including air gaps in element isolation regions and between gate electrodes and a method of manufacturing the same.

### BACKGROUND

Non-volatile semiconductor memory devices using semiconductor elements, such as EEPROMs, AND-type flash memories, NOR-type flash memories, and NAND-type flash memories have been generally known. Among these, the NAND-type flash memories are advantageous in implementing high density arrays because memory cells thereof share source/drain diffusion layers.

At an end of each memory cell array of the NAND-type flash memories, a selection gate transistor controlling the selection of a memory cell block is provided. One of possible methods to further increase the density of NAND-type flash memories is reducing the distance between gate electrodes of two selection gate transistors adjacent to each other.

Certainly, a contact is formed such as penetrating from an upper layer electrode interconnection to the substrate between the gate electrodes of the two adjacent gate selection gate transistors. Accordingly, it is preferable to keep a sufficient process margin in the contact forming process even if the distance between the gate electrodes of the selection gate transistors is reduced.

On the other hand, as the memory cells are miniaturized, the capacitances between the interconnections, between substrates, or between the interconnection and the substrate within a memory cell array will degrade the device characteristics. To solve the above problem, there is a method of providing air gaps in the element isolation regions and between gate electrodes.

### DESCRIPTION OF THE DRAWINGS

FIGS. 1A to 1D are examples of schematic cross-sectional view of a non-volatile semiconductor memory device manufactured by a manufacturing method of an embodiment;

FIG. 2 is an example of an equivalent circuit diagram of the non-volatile semiconductor memory device manufactured by the manufacturing method of the embodiment;

FIG. 3 is an example of a view illustrating an example of the layout of the non-volatile semiconductor memory device manufactured by the manufacturing method of the embodiment;

FIGS. 4A to 4D are examples of schematic cross-sectional views illustrating the method of manufacturing a non-volatile semiconductor memory device according to the embodiment;

FIGS. 5A to 5D are examples of schematic cross-sectional views illustrating the method of manufacturing a non-volatile semiconductor memory device according to the embodiment;

FIGS. 6A to 6D are examples of schematic cross-sectional views illustrating a method of manufacturing a non-volatile semiconductor memory device according to the embodiment;

FIGS. 7A to 7D are examples of schematic cross-sectional views illustrating the method of manufacturing a non-volatile semiconductor memory device according to the embodiment;

FIGS. 8A to 8D are examples of schematic cross-sectional views illustrating the method of manufacturing a non-volatile semiconductor memory device according to the embodiment;

FIGS. 9A to 9D are examples of schematic cross-sectional views illustrating the method of manufacturing a non-volatile semiconductor memory device according to the embodiment;

FIGS. 10A to 10D are examples of schematic cross-sectional views illustrating a method of manufacturing a non-volatile semiconductor memory device according to the embodiment;

FIGS. 11A to 11D are examples of schematic cross-sectional views illustrating the method of manufacturing a non-volatile semiconductor memory device according to the embodiment;

FIGS. 12A to 12D are examples of schematic cross-sectional views illustrating the method of manufacturing a non-volatile semiconductor memory device according to the embodiment;

FIGS. 13A to 13D are examples of schematic cross-sectional views illustrating the method of manufacturing a non-volatile semiconductor memory device according to the embodiment;

FIGS. 14A to 14D are examples of schematic cross-sectional views illustrating the method of manufacturing a non-volatile semiconductor memory device according to the embodiment;

FIGS. 15A to 15D are examples of schematic cross-sectional views illustrating the method of manufacturing a non-volatile semiconductor memory device according to the embodiment;

FIGS. 16A to 16D are examples of schematic cross-sectional views illustrating the method of manufacturing a non-volatile semiconductor memory device according to the embodiment;

FIGS. 17A to 17D are examples of schematic cross-sectional views illustrating the method of manufacturing a non-volatile semiconductor memory device according to the embodiment;

FIGS. 18A to 18D are examples of schematic cross-sectional views illustrating the method of manufacturing a non-volatile semiconductor memory device according to the embodiment;

FIGS. 19A to 19D are examples of schematic cross-sectional views illustrating the method of manufacturing a non-volatile semiconductor memory device according to the embodiment; and

FIGS. 20A to 20D are examples of schematic cross-sectional views illustrating the method of manufacturing a non-volatile semiconductor memory device according to the embodiment.

### DETAILED DESCRIPTION

A example of a method of manufacturing a non-volatile semiconductor memory device, comprising the steps of forming a plurality of element regions and an element isolation region in a semiconductor substrate, the plurality of element regions being extended in a first direction and arranged in parallel, the element isolation region isolating the element regions from each other and being filled with a first insulating film, forming a plurality of memory cell gate electrodes on the element regions, the plurality of memory cell gate electrodes being extended in a second direction and arranged in parallel, the second direction being orthogonal to the first direction; forming two selection gate electrodes on the element regions, the two selection gate electrodes being extended in the second direction and arranged adjacent to each other in parallel, etching the first insulating film in such a manner that the first insulating film remains at least under the selection gate electrodes, after forming the memory cell gate electrodes and selection gate electrodes, forming a first resist pattern opened above a portion between the two selection gate electrodes, forming a second insulating film on the first resist pattern, on the selection gate electrodes, and under the selection gate electrodes in the element isolation region, the second insulating film having an etching rate in an etching solution lower than that of the first insulating film, performing first etching process etching the second insulating film to form a first sidewall insulating film on side surfaces of the selection gate electrodes facing each other, removing the first resist pattern, forming a third insulating film on the memory cell gate electrodes in such a manner that air gaps are formed between the memory cell gate electrodes, forming a second resist pattern opened above the portion between the two selection gate electrodes, performing second etching process using the second resist pattern as a mask to form a second sidewall insulating film on the side surfaces of the selection gate electrodes facing each other, removing the second resist pattern, forming a third resist pattern opened above the portion between the two selection gate electrodes, performing third etching process using the third resist pattern as a mask to remove the first sidewall insulating film and the second sidewall insulating film, removing the third resist pattern, forming a fourth insulating film serving as an etching stopper film on the element regions between the two selection gate electrodes, forming a fifth insulating film on the fourth insulating film, the fifth insulating film filling the portion between the two selection gate electrodes, forming a fourth resist pattern opened above the portion between the two selection gate electrodes, performing fourth etching process using the fourth resist pattern as a mask to remove the fifth insulating film with the fourth insulating film used as an etching stopper, and performing fifth etching process to remove the fourth insulating film, thereby forming a contact hole.

A example of non-volatile semiconductor memory device, comprising, a semiconductor substrate, an element isolation region which is formed in the semiconductor substrate, is extended in a first direction, and separates the semiconductor substrate into element regions, a plurality of memory cell transistors arranged on the element regions, two selection gate transistors arranged on the element regions, a first insulating film formed under the selection gate transistors, a second insulating film arranged on a side surface of the first insulating film on a side toward a direction that selection gate electrodes face each other, a third insulating film arranged on the memory cell transistors, a fourth insulating film in contact with the selection gate transistors and a side surface of the second insulating film, and a contact elect rode arranged between the selection gate transistors.

FIG. 2 is an example of an equivalent circuit diagram of a memory cell portion of a non-volatile semiconductor memory device manufactured by a manufacturing method of the embodiment.

As shown in FIG. 2, a plurality of memory cell transistors MT constitute a memory cell array. In the memory cell array, the memory cell transistors MT are arranged in a column direction (hereinafter, referred to as a first direction or a bit-line direction) and a row direction (hereinafter, referred to as a second direction or a word line direction), that is, in a matrix fashion.

In the memory cell portion, some of the memory cell transistors MT and selection gate transistors STS and STD are connected in series to constitute each NAND string. The length of a repeating unit of the NAND strings is referred to as a string length.

The source region of a memory cell transistor MT located at an end of the array of a group of memory cell transistors MT which constitute each NAND string and are connected in series is connected to the drain region of a selection gate transistor STS for selecting the group of memory cell transistors MT. The drain region of a memory cell transistor MT located at the other end of the array of a group of memory cell transistors MT which constitute each NAND string and are connected in series is connected to the source region of a selection gate transistor STD for selecting the group of memory cell transistors MT.

The source regions of the selection gate transistors STS are connected to a common source line SL.

The gate electrodes of the memory cell transistors MT (memory cell gate electrodes) constitute word lines WL. The word lines WL are connected to word-line switch transistors (not shown). The word lines WL are connected to voltage increasing circuits and the like through the respective word-line switch transistors. The operating voltages applied to the gate electrodes of the word lines WL are controlled by the respective word-line switch transistors.

A common selection gate line SGS for the selection gate transistors STS and a common selection gate line SGD for the selection gate transistors STD are connected to selection gate switch transistors (not shown). The selection gate switch transistors control operating voltages applied to the gate electrodes (selection gate electrodes) of the selection gate transistors STS and STD.

The drains of the selection gate transistors STD are connected to respective bit lines BL through bit-line contacts. The bit lines BL are connected to sense amplifiers (not shown), which amplify data read from the selected memory cell transistor through the respective bit lines BL.

In a NAND-type flash memory, the chip area can be reduced by shortening the string length of NAND strings as a basic repeating unit in the memory cell portion.

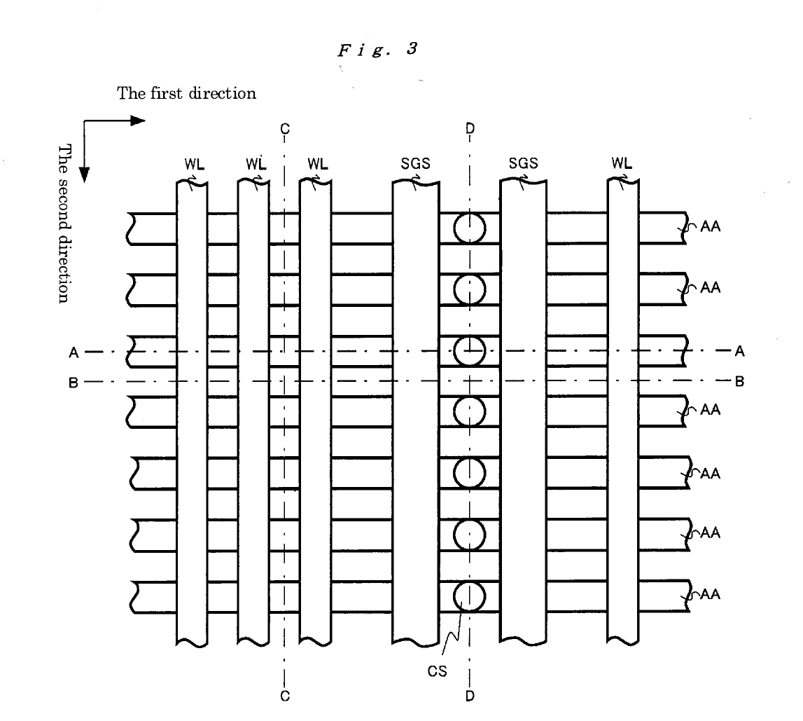

FIG. 3 is a view showing an example of the layout of the memory cell portion of the non-volatile semiconductor memory device manufactured by the manufacturing method of the embodiment. The memory cell portion is formed of plural cell element regions AA, which are extended in the first direction (the bit-line direction) and are arranged in parallel, and element isolation regions, which isolate the cell element regions AA from one another. On the cell element regions AA, the plural word lines WL (the memory cell gate electrodes), which are extended in the second direction (the word-line direction) orthogonal to the first direction and are arranged in parallel, are formed.

On the cell element regions AA, moreover, the two selection gate lines SGS (the selection gate electrodes), which are extended in the second direction and are arranged adjacent to each other in parallel, are formed. Between the two selection gate lines SGS, the source line contacts CS connected to the common source line SL are provided. By reducing the distance between the two selection gate lines SGS, the string length can be shortened.

In the outside of the memory cell portion, a peripheral element region for peripheral transistors is formed but not shown in FIG. 3.

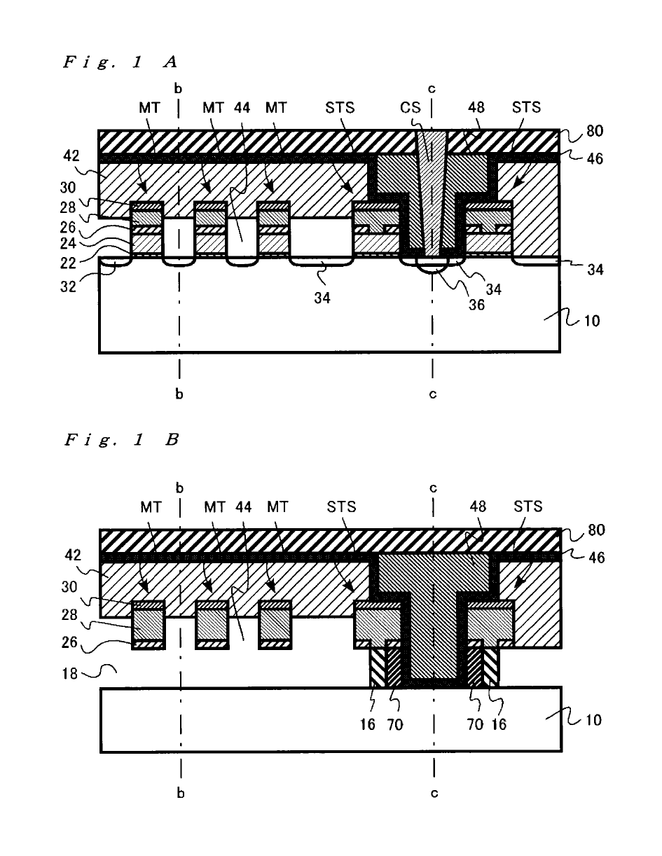

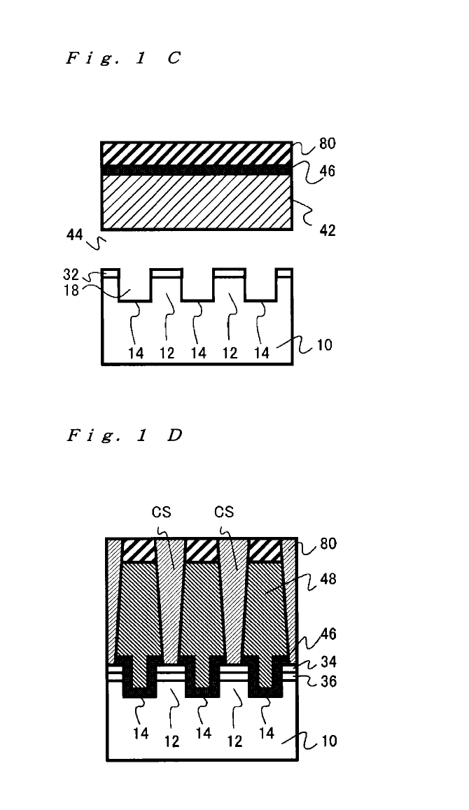

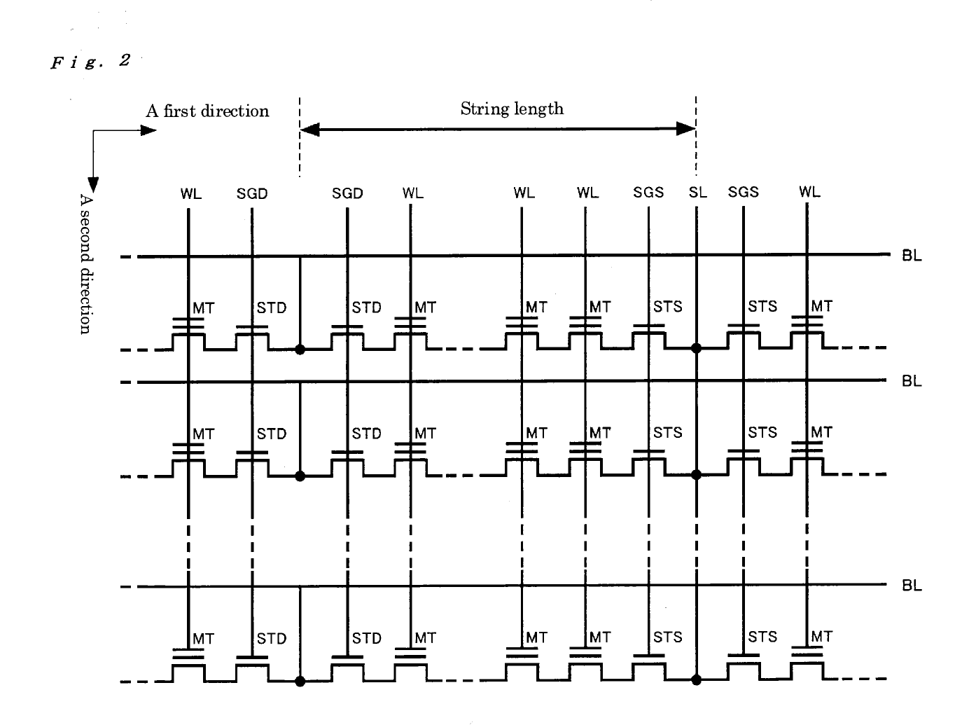

FIGS. 1A to 1D are examples of schematic cross-sectional views of the non-volatile semiconductor memory device manufactured by the manufacturing method of the embodiment. FIGS. 1A to 1C are cross-sectional views along directions A-A, B-B, and C-C of FIG. 3, respectively. FIG. 1C also corresponds to b-b cross-sectional views in FIGS. 1A and 1B. FIG. 1D is an example of a cross-sectional view along a direction D-D of FIG. 3. FIG. 1D also corresponds to c-c cross-sectional views in FIGS. 1A and 1B.

As shown in FIG. 1, the non-volatile semiconductor memory device is formed of a semiconductor substrate 10 of p-type silicon, for example. The impurities of the semiconductor substrate 10 are boron (B), for example.

In the semiconductor substrate 10, cell element regions 12 and element isolation regions 14 isolating the cell element regions 12 from one another are formed. On the cell element regions 12, the memory cell transistors MT and the selection gate transistors STS are formed.

Each element isolation region 14 has an air gap 18. The air gap 18 prevents the inter-element interference between the memory transistors MT which are adjacent to each other across the element isolation region 14. Part of the element isolation region 14 may have an insulating film such as an element isolation insulating film.

Each memory cell transistor MT includes: a gate insulating film 22 formed on the silicon semiconductor substrate 10 and a gate electrode (memory cell gate electrode) formed on the gate insulating film 22. The gate electrode includes a floating gate electrode 24 on the gate insulating film 22, an inter-gate insulating film 26, and a control gate electrode 28. On the control gate electrode 28, a hard mask layer 30 used at gate electrode processing, for example, is formed.

The gate insulating film 22 is formed of a thermally oxidized silicon film, for example. The floating gate electrode 24 is formed of a polycrystalline silicon film, for example. At this point, the floating gate electrode 24 may be change to an insulating film with trap level or laminate structure of a polycrystalline silicon film and insulating film. The inter-gate insulating film 26 is an ONO (oxide-nitride-oxide) film, for example. The control gate electrode 28 is formed of a film stack of a polysilicon film and a tungsten (W) film, for example. The material of the control gate electrode 28 is not particularly limited and may be a silicide film such as a cobalt silicide (CoSi) film or a nickel silicide (NiSi) film, another metal film, or a film stack of a polysilicon and silicide or metal film. The hard mask layer 30 is formed of a silicon nitride film, for example.

The semiconductor substrate 10 of the memory cell portion includes n⁻-type diffusion layers 32 as source/drain regions. The n⁻-type diffusion layers 32 are provided so as to sandwich the memory cell gate electrodes. Each n⁻-type diffusion layer 32 is a diffusion layer containing impurities of arsenic (As), for example.

Each selection gate transistor STS includes an n⁻-type diffusion layer 34 as a source/drain region. In part of the semiconductor substrate 10 between the memory cell gate electrodes, in addition to the n⁻-type diffusion layer 34, an n⁺-type diffusion layer 36 is formed. The n₊-type diffusion layer 36 has a greater junction depth and a higher impurity concentration than those of the n⁻-type diffusion layer 34. The n⁻-type and n⁺-type diffusion layers 34 and 36 are diffusion layers containing impurities of arsenic (As), for example.

Over the memory cell gate electrodes, an interlayer insulating film (third insulating film) 42 is formed. Between each pair of adjacent memory cell gate electrodes, air gaps 44 are formed. The air gaps 44 reduce the inter-wire capacitance between the memory cell gate electrodes and the capacitance between the memory cell gate electrodes and semiconductor substrate 10. The interlayer insulating film 42 is formed of a plasma TEOS (tetraethyl orthosilicate) film or a plasma SiH4 film formed by plasma CVD (chemical vapor deposition), for example.

On the interlayer insulating film 42 and between the selection gate electrodes, an etching stopper film (fourth insulating film) 46 is formed. The etching stopper film 46 serves as an etching stopper in the process of forming the source-line contacts CS. The etching stopper film 46 is also provided on side surfaces of the etching protection film. The etching stopper film 46 is a silicon nitride film, for example.

The portion between the selection gate electrodes is filled with interlayer insulating film (fifth insulating film) 48 on the etching stopper film 46. The interlayer insulating film 48 is formed of a BPSG (boron phosphorous doped silicate glass) film, for example. Furthermore, source lines (not shown) and the source-line contacts CS connecting the source/drain regions of the selection gate transistors STS are formed. The lowest part of the interlayer insulating film 48 is located below the lower surfaces of the source-line contacts CS.

Furthermore, on the interlayer insulating film (the fifth insulating film) 48, interlayer insulating film 80 is formed. The interlayer insulating film 80 is formed of a plasma TEOS film or a plasma SiH4 film, for example.

At the bottom between the selection gate electrodes, for example, a not-shown oxidized silicon film may be formed under the etching stopper film 46. The lowest part of the etching stopper film 46 is located below the lower surfaces of the source-line contacts CS.

Under the selection gate electrodes, an element isolation insulating film 16 partially remains. On the gate edge portions under the selection gate electrodes in a direction that the selection gate electrodes face each other, an etching protection film (a second insulating film) 70 is formed. In other words, the element isolation insulating film 16 located under each selection gate electrode is in contact with the etching protection film 70 on a side toward the direction that the selection gate electrodes face each other. Moreover, the element isolation insulating film 16 located under each selection gate electrode is in contact with the air gap 18 on the side opposite to the direction that the selection gate electrodes face each other.

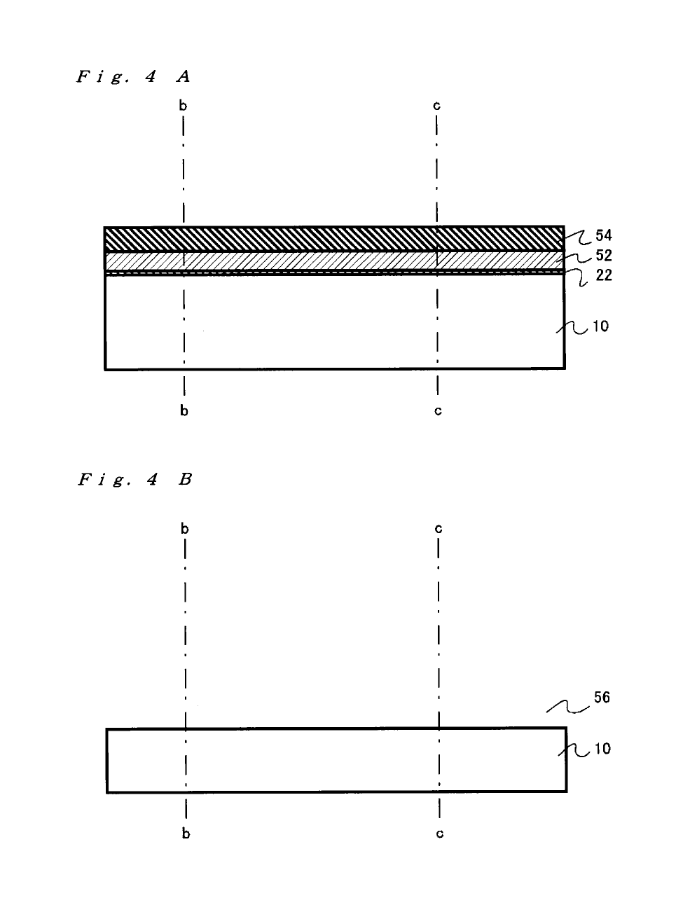

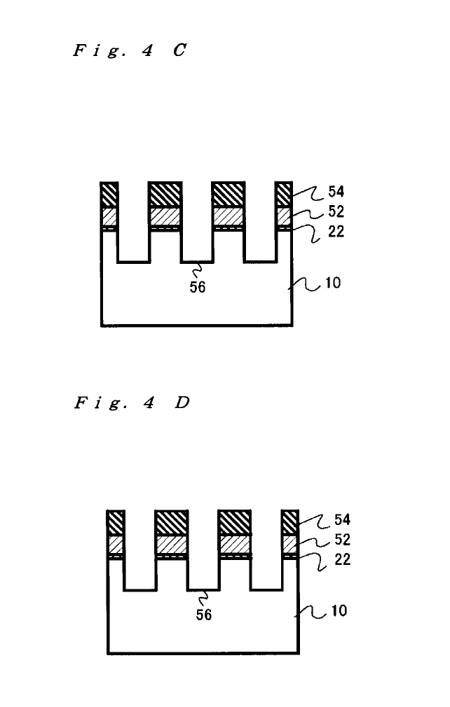

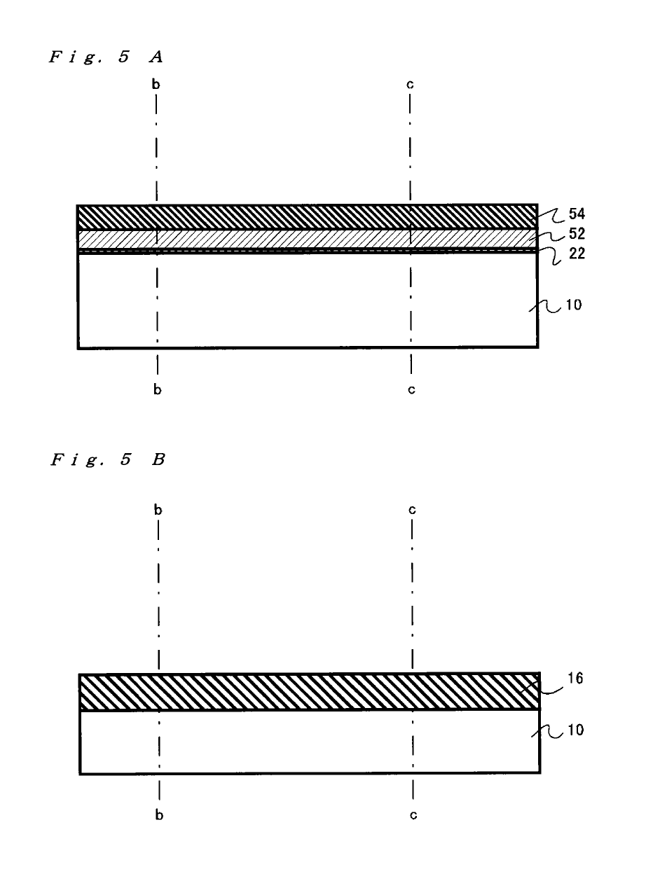

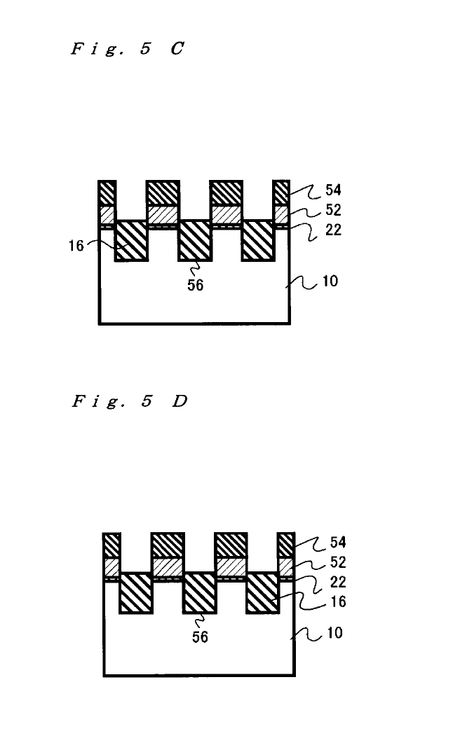

Next, a description is given of the method of manufacturing a semiconductor memory device of the embodiment with reference to FIGS. 4A to 20D. FIGS. 4A to 20D are just examples of schematic cross-sectional views illustrating the method of manufacturing a semiconductor memory device of the embodiment. For example, FIGS. 4A to 4D are cross-sectional views at positions corresponding to FIGS. 1A to 1D, respectively. FIGS. 5A to 5D to FIGS. 20A to 20D are also cross sectional views at the same positions.

As shown in FIGS. 4A to 4D, the gate insulating film 22 is formed on the semiconductor substrate 10 of p-type silicon by thermal oxidation. Next, on the gate insulating film 22, a polycrystalline silicon film 52 containing impurities of phosphor (P) or boron (B) for forming floating gate electrodes is deposited by LPCVD. Thereafter, a silicon nitride film 54 is formed by LPCVD.

The silicon nitride film 54 is patterned by lithography and RIE (reactive ion etching) as dry etching. Using the patterned silicon nitride film 54 as a mask material, the polycrystalline silicon film 52, gate insulating film 22, and semiconductor substrate 10 are sequentially etched by RIE to form trenches 56 in which the element isolation regions are formed.

As shown in FIGS. 5A to 5D, the trenches 56 are filled with the element isolation insulating film (first insulating film) 16. The element isolation insulating film 16 is formed of an oxidized silicon film having a higher etching rate in an etching solution (e, q, hydrofluoric acid, ammonium fluoric acid) than that of a thermally-oxidized silicon film. The element isolation insulating film 16 is formed by using a SOG (spin on glass) polysilazane film, for example. The oxidized silicon film formed by using the polysilazane film has an etching rate in hydrofluoric acid about one hundred times that of the thermally-oxidized silicon film, for example. After the trenches 56 are filled, the obtained product is flattened by CMP (chemical mechanical polishing), for example, and is etched back by RIE, for example.

In such a manner, the plural cell element regions 12, in each of which the memory cell transistors MT and selection gate transistors STS are formed and which extend in parallel in the first direction, and the element isolation regions 14, which isolate the cell element regions 12 from one another, are formed.

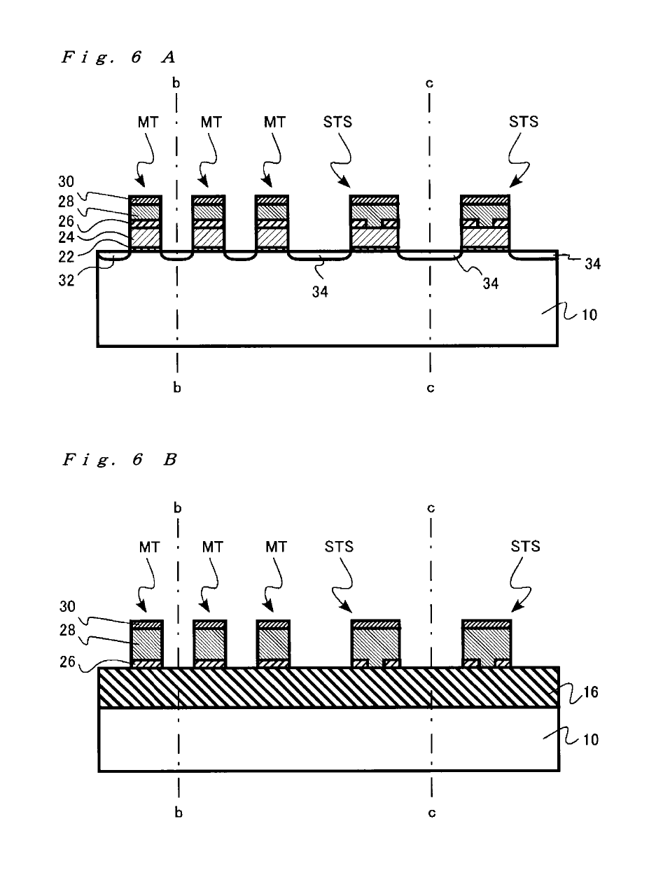

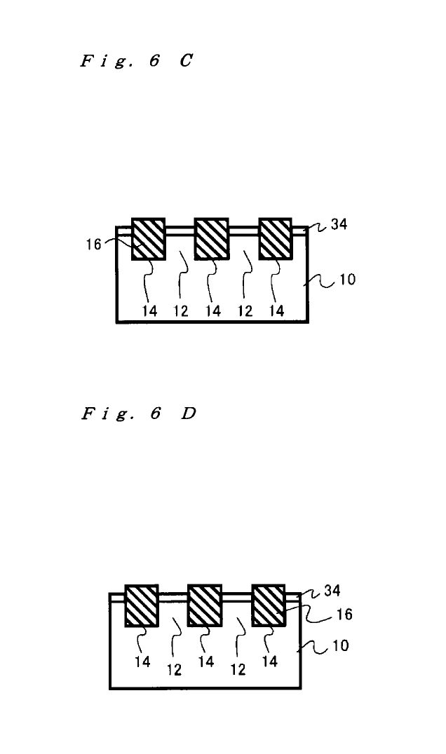

As shown in FIGS. 6A to 6D, the silicon nitride film 54 is removed by a wet etching such as phosphoric acid process, for example. As the inter-gate insulating film 26, an ONO film is formed, for example. For a control gate electrodes 28, a film stack formed of a polycrystalline silicon film containing impurities of phosphor (P) or boron (B), a tungsten nitride (WN) film, and a tungsten (W) film is formed, for example. The ONO film is opened at the portions corresponding to the selection gate electrode and peripheral gate electrodes.

Furthermore, on the polycrystalline silicon film, the hard mask layer 30 of a silicon nitride film used at gate electrode processing is formed. The hard mask layer 30 is patterned by lithography and RIE.

Using the patterned hard mask layer 30 as a mask, the film stack of the polycrystalline silicon film, a tungsten nitride (WN) film, and a tungsten (W) film, an ONO film, and polycrystalline silicon film 52 are sequentially etched by RIE to form the memory cell gate electrodes, selection gate electrodes, and peripheral gate electrodes.

In the aforementioned manner, the plural memory cell gate electrodes, which are extended in the second direction orthogonal to the first direction and are arranged adjacent to one another in parallel, are formed on the cell element regions (first element regions) 12. Moreover, the two selection gate electrodes, which are extended in the second direction and arranged adjacent to each other in parallel, are formed on the cell element regions 12. Furthermore, the peripheral gate electrodes are formed in a not-shown peripheral element region.

Thereafter, the n⁻-type diffusion layers 32 and 34 are formed by ion implantation of arsenic (As) using the memory cell gate electrodes and selection gate electrodes as a mask, for example. The n⁻-type diffusion layers 32 and 34 may be formed either simultaneously or separately. After the ion implantation, heat treatment is performed for activation. In the heating process, diffusion layer is not formed on part of the semiconductor substrate 10 covered with the element isolation insulating film 16. Because of the element isolation insulating film 16, impurities do not reach the semiconductor substrate 10.

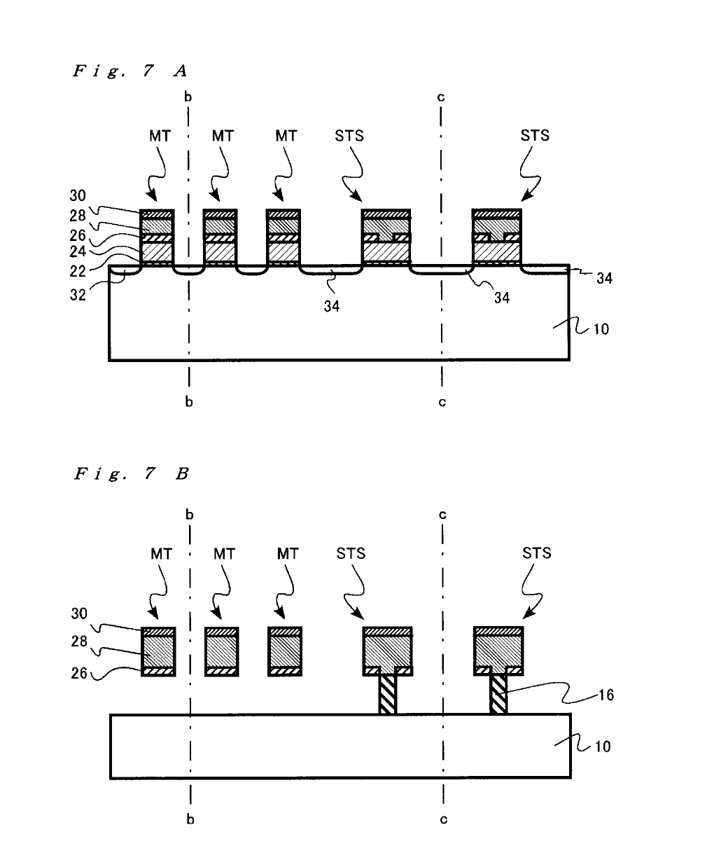

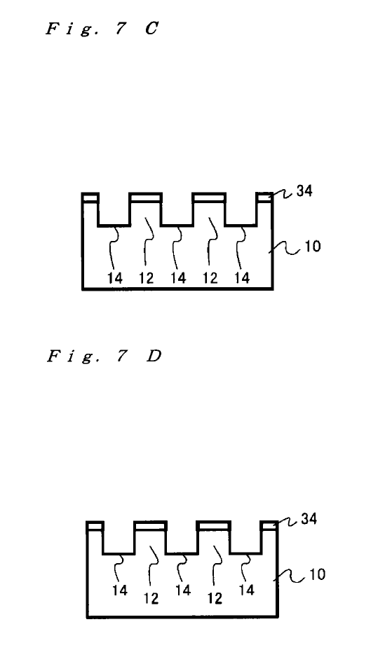

As shown in FIGS. 7A to 7D, after the memory cell gate electrodes and selection gate electrodes are formed, the element isolation insulating film (first insulating film) 16 is etched in such a manner as to remain at least under the selection gate electrodes. The above etching is buffered hydrofluoric acid treatment performed as a posttreatment after the gate electrode processing by RIE, for example.

The element isolation insulating film (first insulating film) 16 is formed of an insulating film having a high etching rate in hydrofluoric acid, such as a polysilazane film, for example. Accordingly, the element isolation insulating film 16 is etched more largely than the gate insulating film 22 of the thermally oxidized silicon film by buffered hydrofluoric acid treatment performed as the posttreatment after the gate electrode processing, for example.

In the process of etching, the etching time is appropriately controlled, for example, in such a manner that the element isolation insulating film (first insulating film) 16 remains under the selection gate electrodes. This is for preventing to fill the air gaps in the element isolation regions 14 and between the memory cell gate electrodes with the insulating film in a process of depositing insulating film having good step coverage later.

Moreover, in the process of etching the element isolation insulating film (first insulating film) 16, as shown in FIGS. 7A to 7D, it is preferable that air gaps penetrating the element isolation insulating film (first insulating film) 16 be formed under the memory cell gate electrodes. This is because the thus-formed air gaps can greatly reduce the capacitances between the element regions and between interconnections and the substrate.

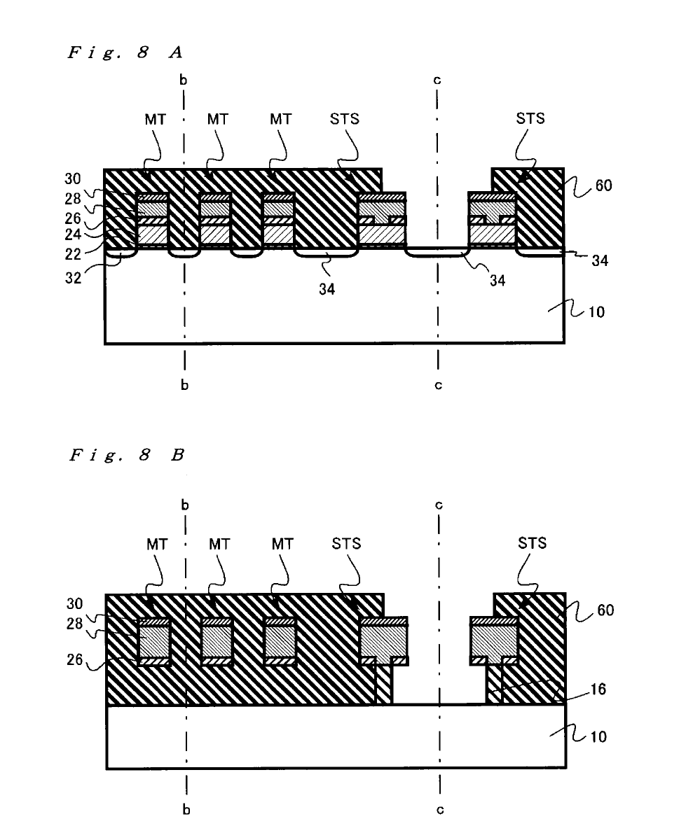

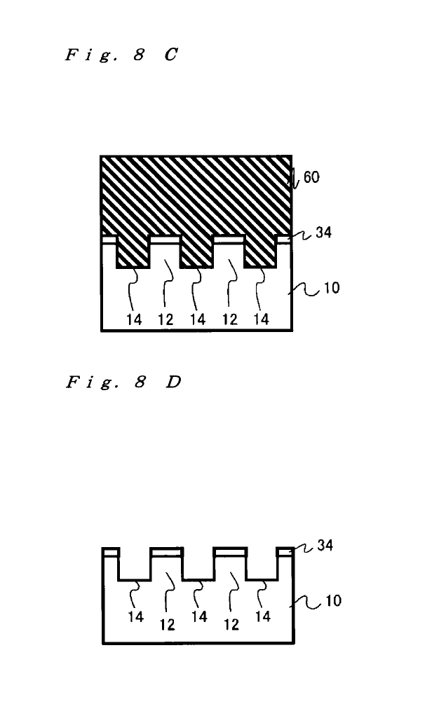

As shown in FIGS. 8A to 8D, a first resist pattern 60 opened between the two selection gate electrodes is formed.

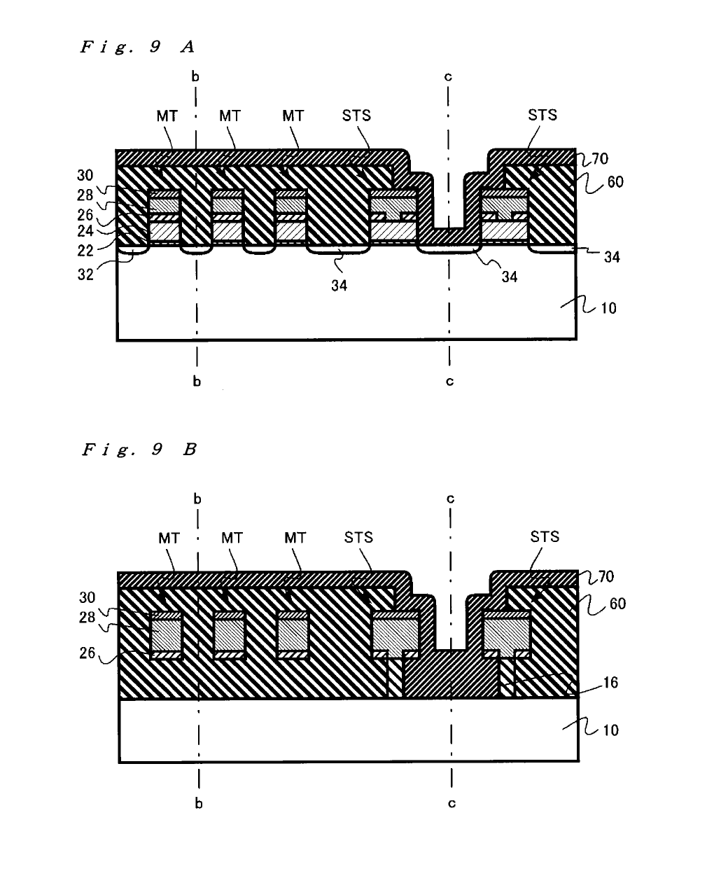

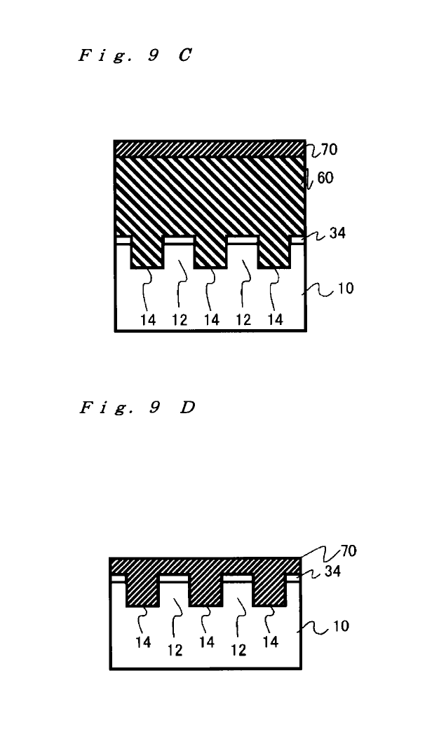

As shown in FIGS. 9A to 9D, an etching protection film (second insulating film) 70 having an etching rate in, for example, hydrofluoric acid lower than that of the element isolation insulating film (first insulating film) 16 in, for example, hydrofluoric acid is formed on a first resist pattern 60, on the selection gate electrodes, and under the selection gate electrodes in the element isolation regions. The etching protection film (second insulating film) 70 is formed of oxidized silicon film using by plasma CVD at room temperature (not lower than 10° C. and not higher than 60° C.), for example. The etching protection film (second insulating film) 70 is formed on the side surface of the element isolation insulating film (first insulating film) 16 remaining under each selection gate electrode, the side surface being located on the side closer to the adjacent selection gate electrode in the direction that the selection gate electrodes face each other.

It is preferable that the etching rate of the etching protection film (second insulating film) 70 in, for example, hydrofluoric acid is not higher than 1/10 of that of the element isolation insulating film (first insulating film) 16 in, for example, hydrofluoric acid. This can sufficiently prevent the element isolation insulating film (first insulating film) 16 remaining under the selection gate electrodes from being etched in the later process of wet etching.

It is preferable that the film thickness of the etching protection film (second insulating film) 70 is not less than half the width of each element isolation region 14 in the second direction (the word-line or row direction). This causes the element isolation regions 14 to be completely filled.

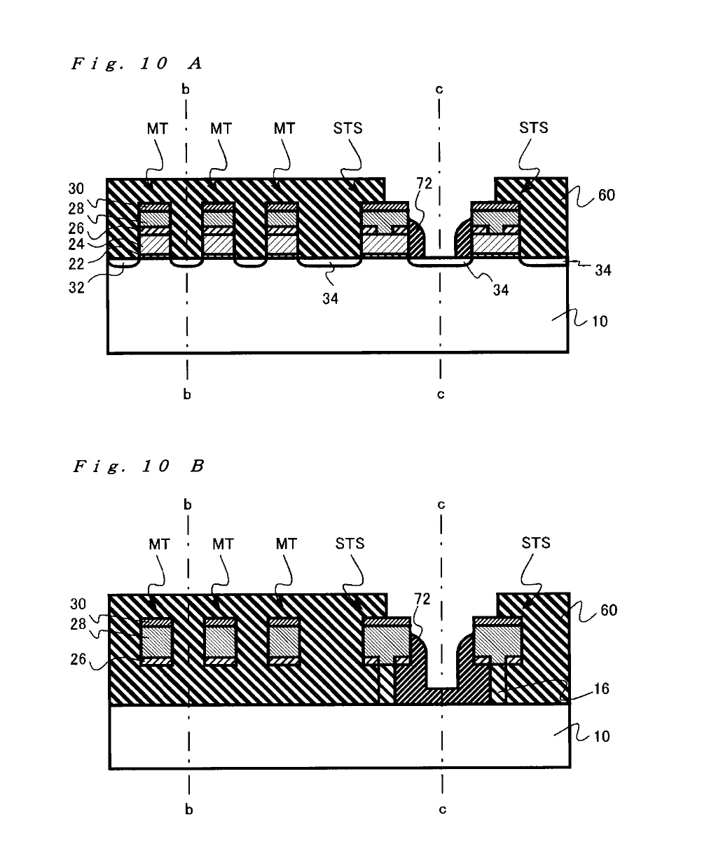

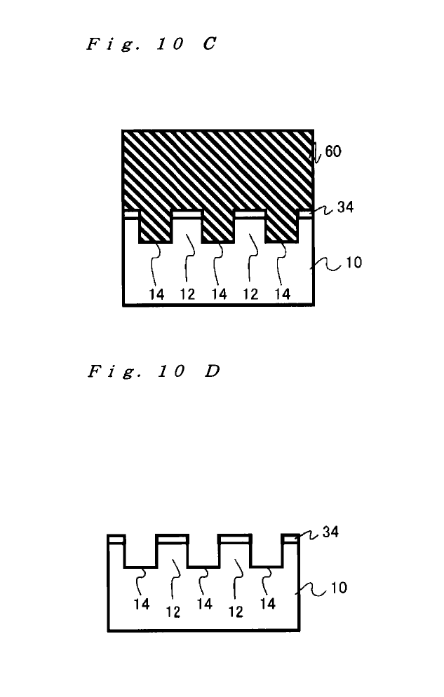

As shown in FIG. 10A to 10D, a first etching process which etches the etching protection film (second insulating film) 70 is performed to form a first sidewall insulating film 72 on the side surfaces of the selection gate electrodes facing each other. The first etching process is performed by highly-anisotropic RIE, for example.

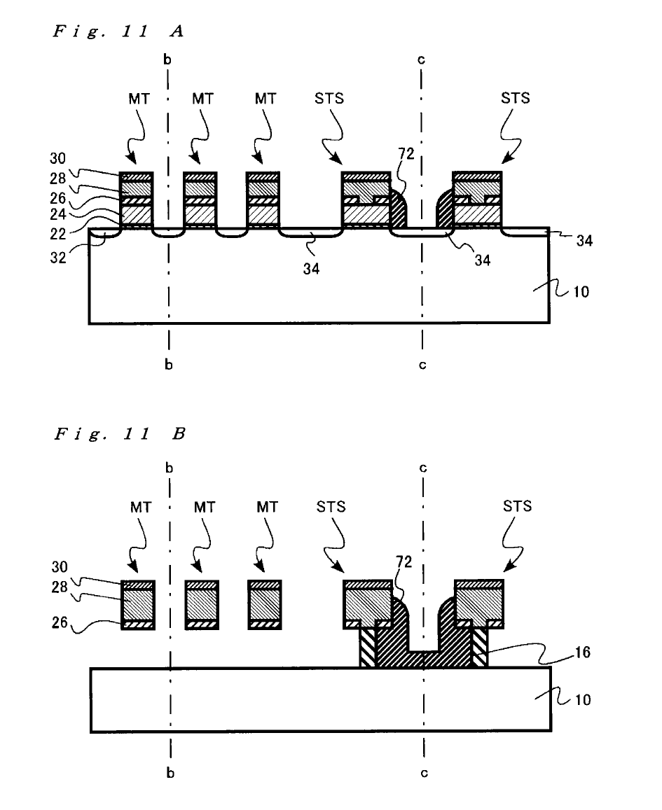

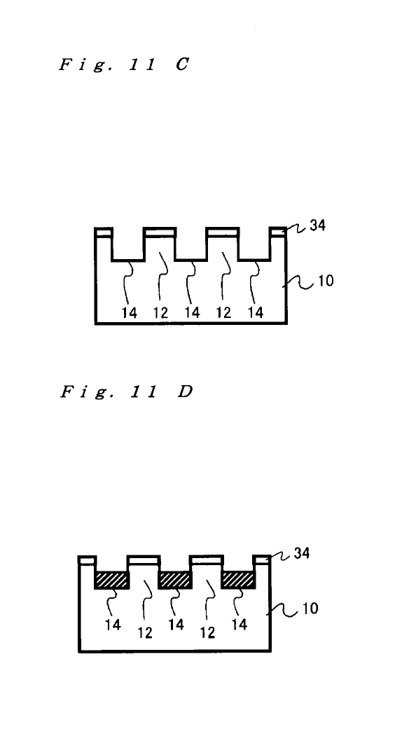

As shown in FIGS. 11A to 11D, the first resist pattern 60 is removed.

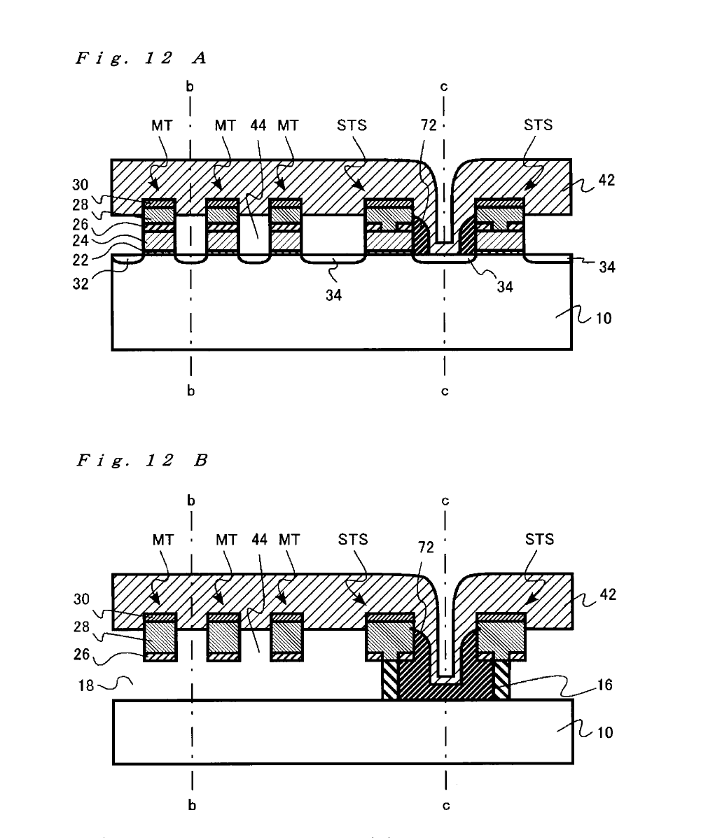

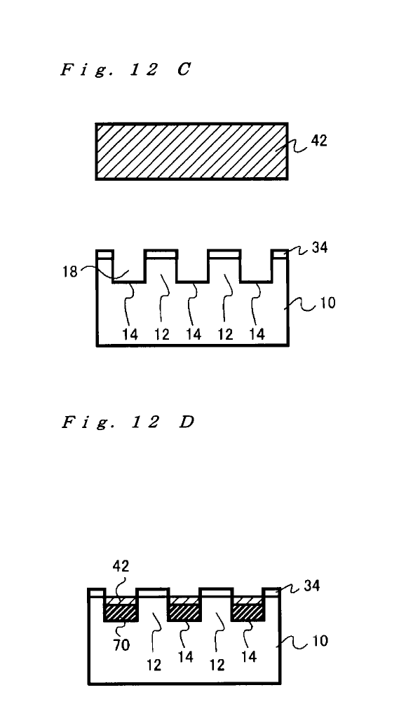

As shown in FIGS. 12A to 12D, an interlayer insulating film (third insulating film) 42 is formed over the memory cell gate electrodes in such a manner that the air gaps 18 and 44 are formed between the adjacent element regions 12 and between the memory cell gate electrodes, respectively. The air gaps 18 and 44 reduces the capacitances between the interconnections of the memory cell gate electrodes and between the memory cell gate electrodes and the substrate, thus preventing malfunction due to interferences between the memory cells and preventing wiring delay. The air gaps 18 and 44 is formed by using the interlayer insulating film 42 whose step coverage is worse than that of the etching protection film (second insulating film) 70, for example, such as a plasma TEOS film or a plasma SiH4 film. In other words, the step coverage of the etching protection film (second insulating film) 70 is better than that of the interlayer insulating film (third insulating film) 42.

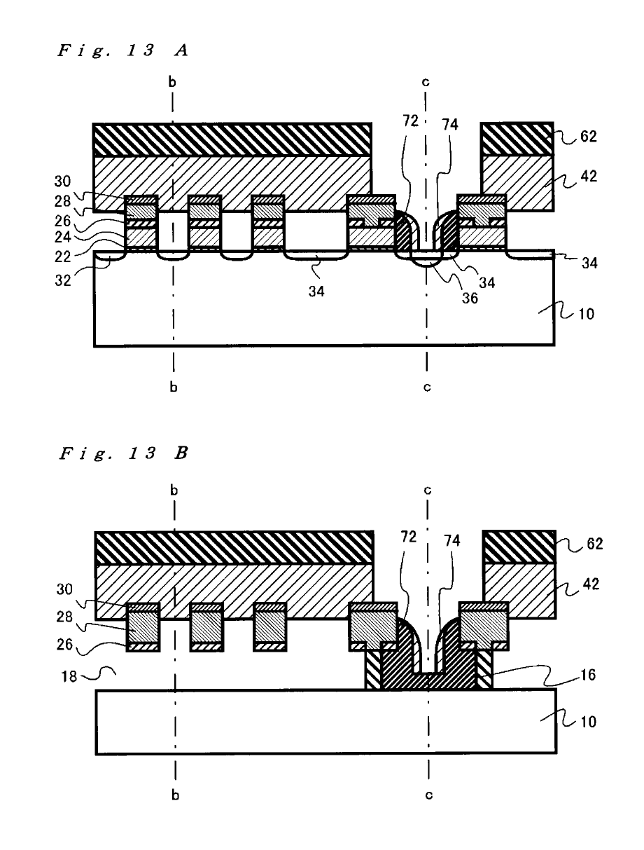

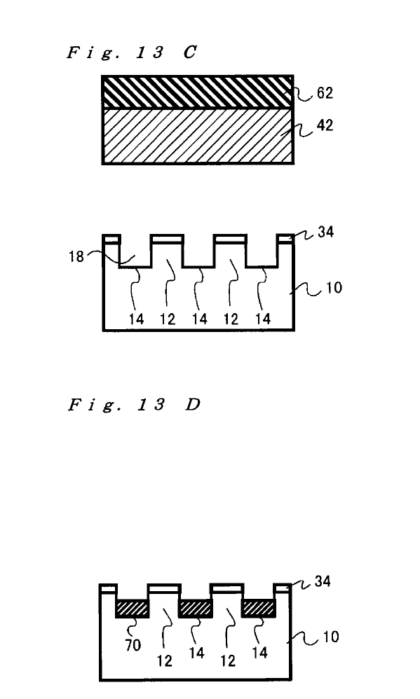

As shown in FIGS. 13A to 13D, a second resist pattern 62 opened above the portion between the two selection gate electrodes is formed. Second etching process is then performed using a second resist pattern 62 as a mask to form a second sidewall insulating film 74 on the side surfaces of the selection gate electrodes facing each other. The second etching process is performed by highly anisotropic RIE, for example.

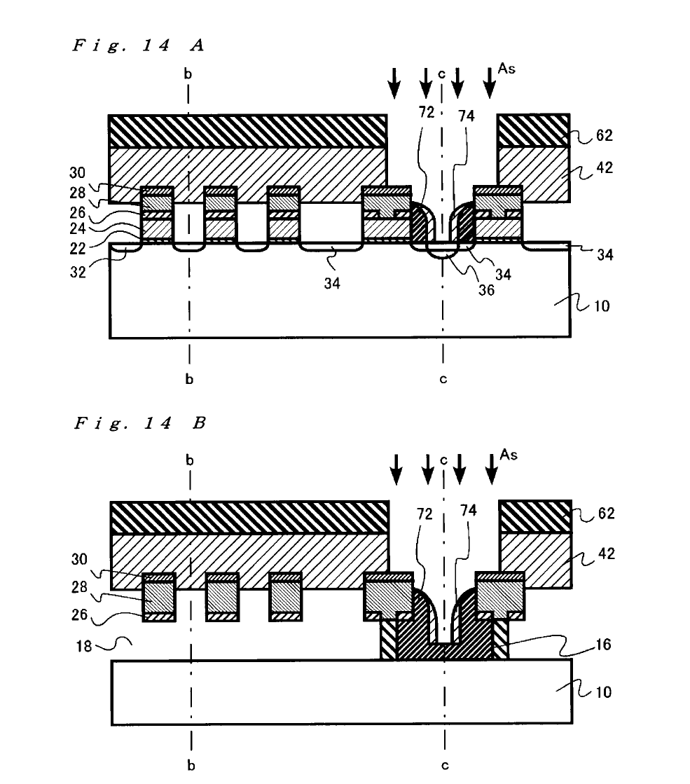

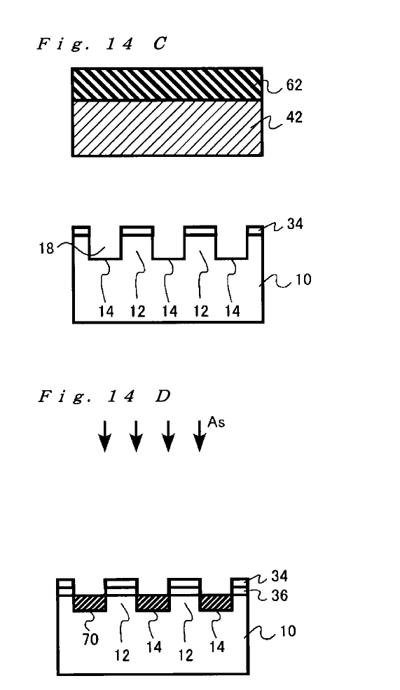

As shown in FIGS. 14A to 14D, using the second resist pattern 62 and second sidewall insulating film 74 as a mask, impurities are injected into the element region between the two selection gate electrodes by ion-implanted method. For example, arsenic (As) is injected to form the n⁺-type diffusion layer 36. In the same process, for the transistors of the peripheral circuit, a sidewall insulating film corresponding to the second sidewall insulating film 74 and an n⁺-type diffusion layer may be formed. In the case of simultaneously forming the sidewall insulating film for the transistors of the peripheral circuit portion, the second resist pattern 62 only needs to be a pattern opened in gate electrode edge portions of the peripheral circuit portion.

As for the ion implantation of impurities, the impurities may be injected over the entire surface after the second resist pattern 62 is removed. Alternatively, ion implantation may be performed using a mask of another resist pattern.

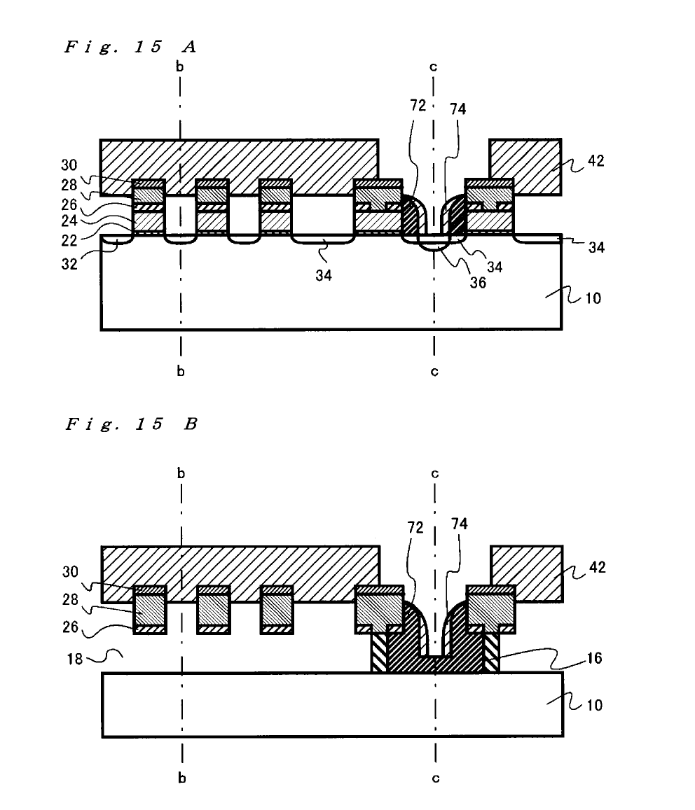

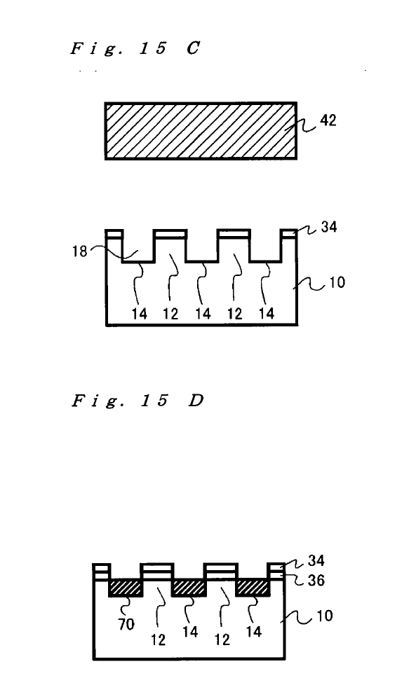

As shown in FIGS. 15A to 15D, the second resist pattern 62 is removed.

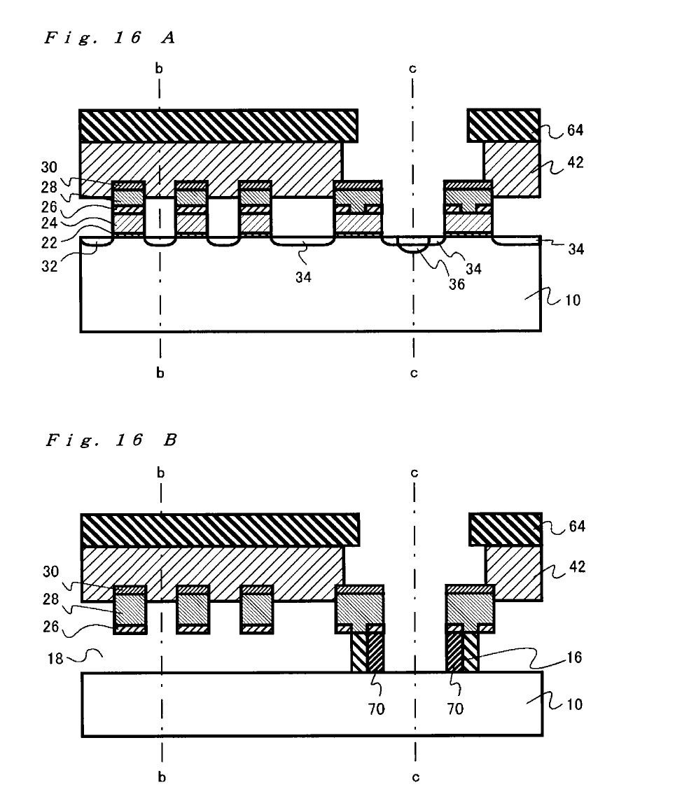

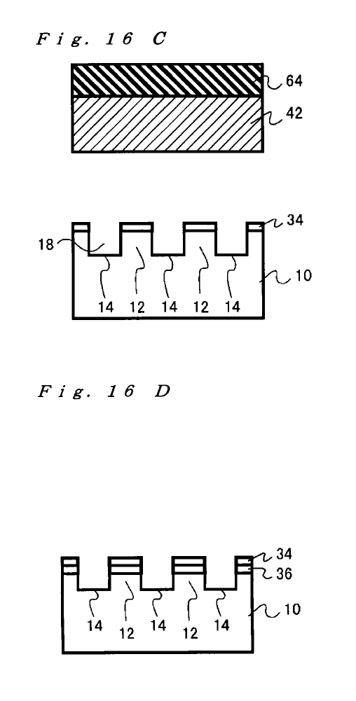

As shown in FIGS. 16A to 16D, a third resist pattern 64 opened above the portion between the two selection gate electrodes is formed. Using the third resist pattern 64 as a mask, third etching process is performed to remove the first sidewall insulating film 72 and second sidewall insulating film 74. In the same process, part of the etching protection film (second insulating film) 70 may be removed.

The third etching process is isotropic wet etching, for example. The chemical for the wet etching is diluted ammonium solution, for example.

For the sidewall insulating film of the selection gate electrodes is removed as described above, the margin for contact hole openings can be increased in the later process of forming contact holes even when the distance between the selection gate electrodes is reduced. In other words, by forming the contact pattern on the sidewall insulating film, it is possible to prevent the problems that the contact opening area is reduced or the contact remains unopened.

In the aforementioned wet etching process, the etching protection film (second insulating film) 70 is present on the element isolation regions under the selection gate electrodes, and therefore, the element isolation insulating film (first insulating film) 16 which has a high wet-etching rate and remains under the selection gate electrodes is prevented from being etched.

Moreover, because of the presence of the etching protection film (second insulating film) 70, the gate insulating film 22 of the selection gate electrodes and memory cell gate electrodes can be prevented over-etched in the process of removing the sidewall insulating film of the selection gate electrodes by the wet etching process.

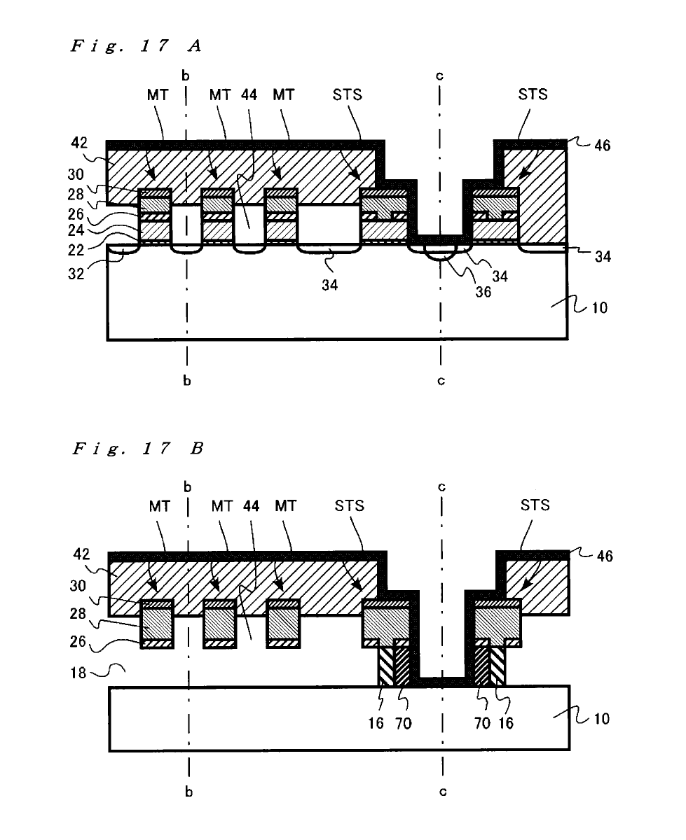

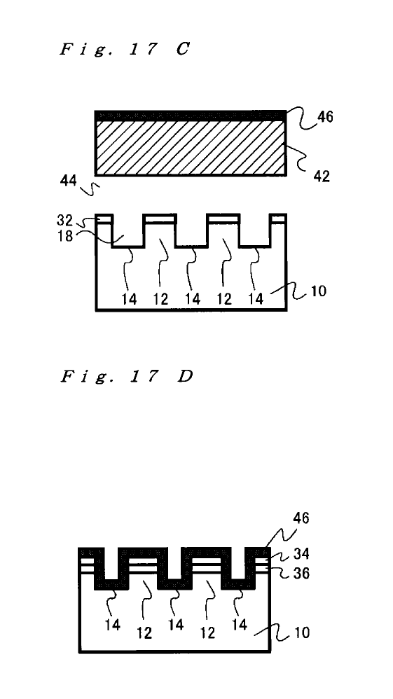

As shown in FIGS. 17A to 17D, the third resist pattern 64 is removed. An etching stopper film (fourth insulating film) 46 is formed on the interlayer insulating film 42 and on the element regions between the two selection gate electrodes. The etching stopper film 46 is a silicon nitride film formed by LPCVD, for example.

In the aforementioned process, for the etching protection film (second insulating film) 70 is present in the element isolation regions under the selection gate electrodes, the air gaps 18 and 44 of the memory cell array portion are not filled with the etching stopper film 46 even if the etching stopper film 46 is formed of a film which is formed by LPCVD and has good step coverage.

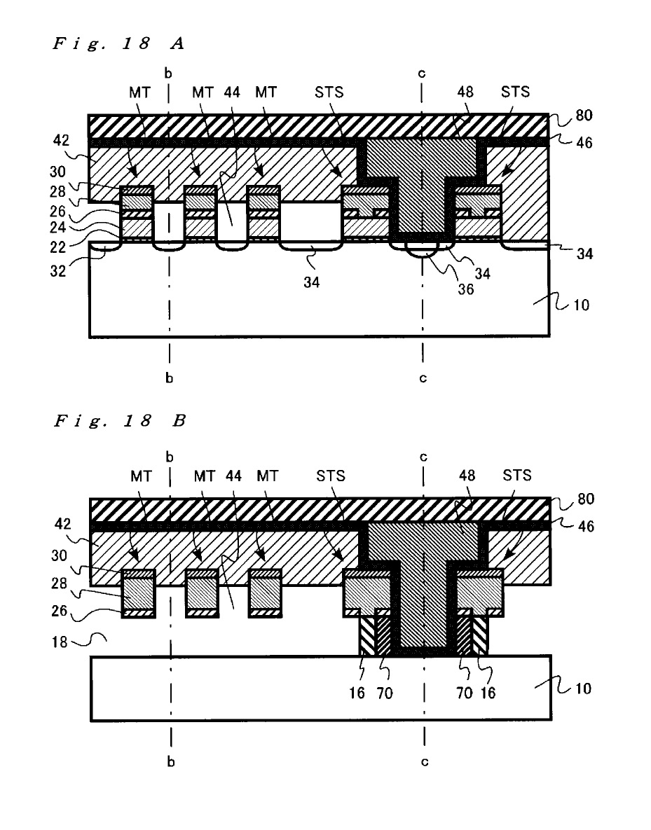

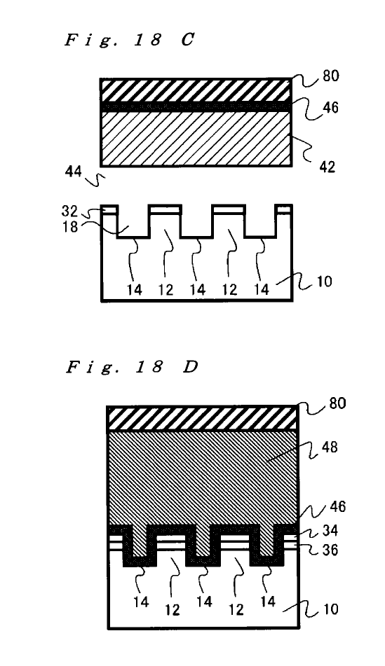

As shown in FIGS. 18A to 18D, an interlayer insulating film (fifth insulating film) 48 is formed on the etching stopper film (fourth insulating film) 46 to fill the portion between the two selection gate electrodes. The interlayer insulating film (fifth insulating film) 48 is a BPSG film formed by LPCVD, for example. Thereafter, the interlayer insulating film 48 is flattened by CMP. The interlayer insulating film (fifth insulating film) 48 is made of a material whose etching rate is higher at the later dry etching (third etching process) than that of the etching stopper film (fourth insulating film) 46.

Furthermore, interlayer insulating film 80 is formed on the interlayer insulating film (fifth insulating film) 48. The interlayer insulating film 80 is a plasma TEOS film or a plasma SiH4 film, for example.

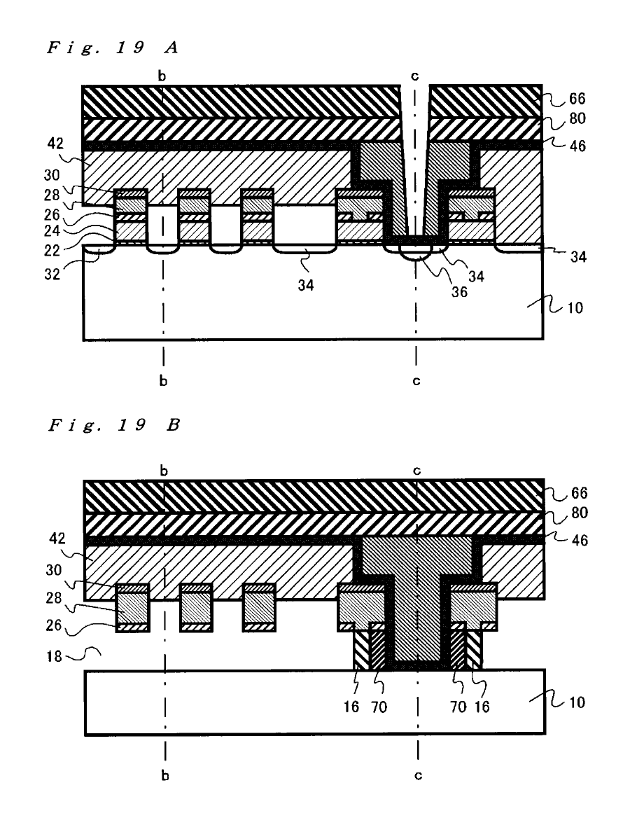

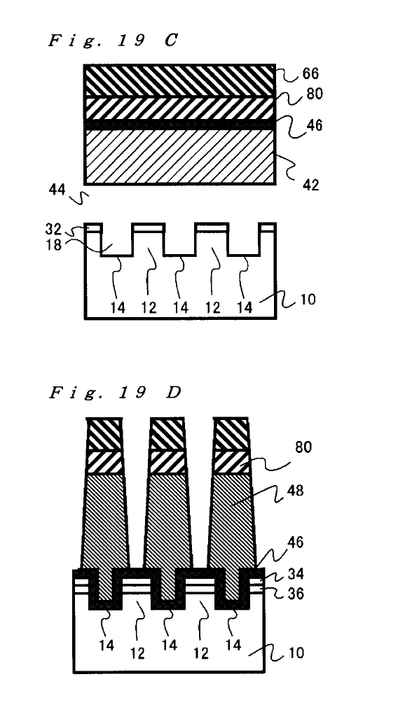

As shown in FIGS. 19A to 19D, a fourth resist pattern 66 partially opened above the portion between the two selection gate electrodes is formed, and using the fourth resist pattern 66 as a mask, fourth etching process is performed. By the fourth etching process, the interlayer insulating film and interlayer insulating film (fifth insulating film) 48 are removed using the etching stopper film (fourth insulating film) 46 as an etching stopper.

The fourth etching process is performed by dry etching such as RIE. The dry etching is performed under the condition of a high etching selection ratio to the etching stopper film (fourth insulating film) 46.

By using the etching stopper film 46 as the etching stopper as described above, the etching amount can be sufficiently ensured in the process of etching the interlayer insulating film 80 and interlayer insulating film (fifth insulating film) 48, so that contact holes can be stably formed with a wide process margin.

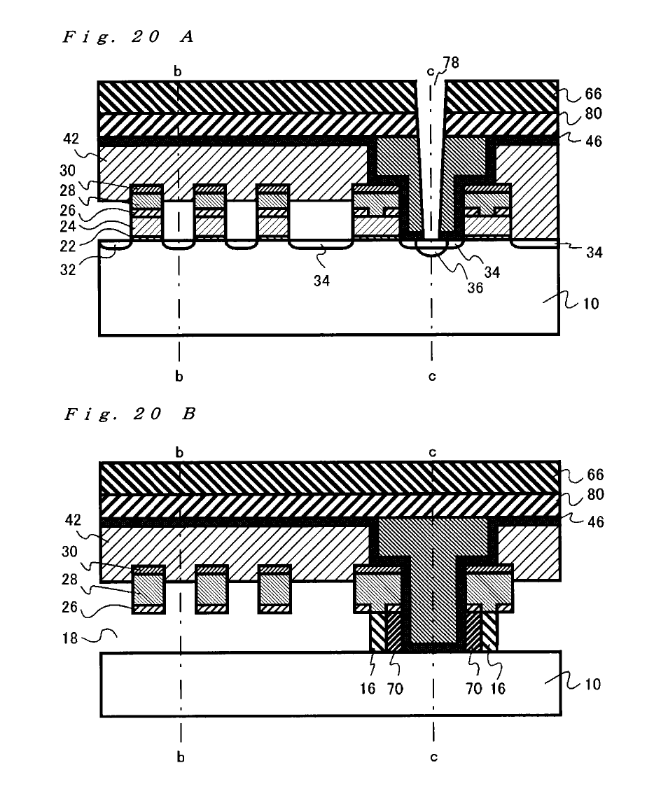

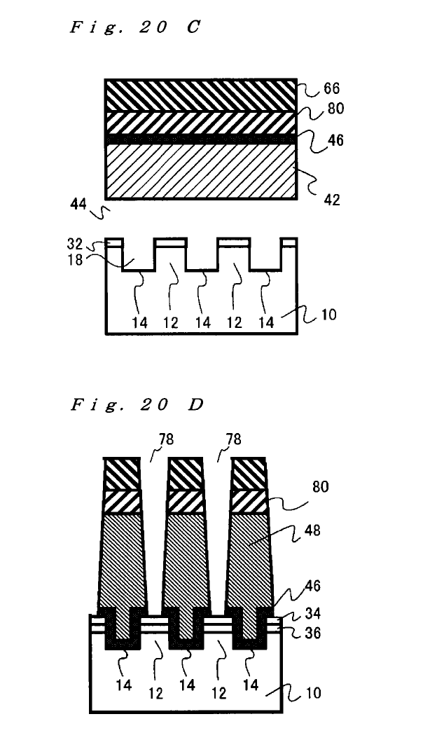

As shown in FIGS. 20A to 20D, the fifth etching process is performed to remove the etching stopper film (fourth insulating film) 46 for formation of contact holes 78. The fifth etching process is performed by dry etching such as RIE.

Thereafter, the fourth resist pattern 66 is removed, and in each contact hole 78, for example, a metal plug (contact electrode) is formed. The source-line contact CS is thus formed as shown in FIGS. 1A to 1D. For example, the metal plug is formed by depositing a titanium nitride (TiN) film serving as a barrier metal by CVD, for example, then depositing a tungsten (W) film by CVD, and removing the film other than the inside part of the contact hole 78.

Subsequently, a publicly-known process technique is employed to form electrode interconnections in upper layers and the like, thus forming the non-volatile semiconductor memory device.

As described above, according to the method of manufacturing a non-volatile semiconductor device of this embodiment, it is possible to provide a manufacturing method capable of forming air gaps in the element isolation regions and between the gate electrodes while ensuring the process margin of the contact forming process.

The above description is given of the embodiment of the present invention with reference to the concrete example. The above-described embodiment is shown just byway of example and will not limit the present invention. Moreover, in the description of the embodiment, no description is given of the portions of the non-volatile semiconductor memory device and the method of manufacturing the non-volatile semiconductor memory device not directly needed and the like. However, it is possible to properly select and use necessary elements concerning the non-volatile semiconductor memory device and the method of manufacturing the non-volatile semiconductor memory device.

For example, the example of the pattern of contact holes described in the embodiment is the circular pattern shown in FIGS. 3A to 3D. However, the pattern of contact holes is not limited to the circular shape. For example, the pattern of contact holes may be a rectangular pattern opened between the two-selection gate electrodes continuously in the row-direction (second direction). Alternatively, the pattern of contact holes may be elliptical.

Moreover, for example, in the embodiment, the description is given of the region of the selection gate transistors STS in which the source-line contacts CS are formed. However, the same manufacturing method is applicable to the regions of the selection gate transistors STD in which the bit-line contacts are formed.

In addition, all the matters in the method of manufacturing the non-volatile semiconductor memory device whose design can be properly changed by those skilled in the art are included in the scope of the present invention, which is defined by claims and the equivalents thereof.

What is claimed is:

1. A method of manufacturing a non-volatile semiconductor memory device, comprising the steps of:
forming a plurality of element regions and an element isolation region in a semiconductor substrate, the plurality of element regions being extended in a first direction and arranged in parallel, the element isolation region isolating the element regions from each other and being filled with a first insulating film;
forming a plurality of memory cell gate electrodes on the element regions, the plurality of memory cell gate electrodes being extended in a second direction and arranged in parallel, the second direction being orthogonal to the first direction;
forming two selection gate electrodes on the element regions, the two selection gate electrodes being extended in the second direction and arranged adjacent to each other in parallel;
etching the first insulating film in such a manner that the first insulating film remains at least under the selection gate electrodes, after forming the memory cell gate electrodes and selection gate electrodes;
forming a first resist pattern opened above a portion between the two selection gate electrodes;
forming a second insulating film on the first resist pattern, on the selection gate electrodes, and under the selection gate electrodes in the element isolation region, the second insulating film having an etching rate in an etching solution lower than that of the first insulating film;
performing first etching process etching the second insulating film to form a first sidewall insulating film on side surfaces of the selection gate electrodes facing each other;
removing the first resist pattern;
forming a third insulating film on the memory cell gate electrodes in such a manner that air gaps are formed between the memory cell gate electrodes;
forming a second resist pattern opened above the portion between the two selection gate electrodes;
performing second etching process using the second resist pattern as a mask to form a second sidewall insulating film on the side surfaces of the selection gate electrodes facing each other;
removing the second resist pattern;
forming a third resist pattern opened above the portion between the two selection gate electrodes;
performing third etching process using the third resist pattern as a mask to remove the first sidewall insulating film and the second sidewall insulating film;
removing the third resist pattern;
forming a fourth insulating film serving as an etching stopper film on the element regions between the two selection gate electrodes;
forming a fifth insulating film on the fourth insulating film, the fifth insulating film filling the portion between the two selection gate electrodes;
forming a fourth resist pattern opened above the portion between the two selection gate electrodes;
performing fourth etching process using the fourth resist pattern as a mask to remove the fifth insulating film with the fourth insulating film used as an etching stopper; and
performing fifth etching process to remove the fourth insulating film, thereby forming a contact hole.

2. The method of manufacturing a non-volatile semiconductor memory device according to claim 1, wherein when the first insulating film is etched, air gaps are formed under the memory cell gates penetrating to the first direction.

3. The method of manufacturing a non-volatile semiconductor memory device according to claim 1, wherein the etching rate of the second insulating film in the etching solution is not higher than 1/10 of that of the first insulating film in the etching solution.

4. The method of manufacturing a non-volatile semiconductor memory device according to claim 1, wherein the second insulating film has better step coverage than the third insulating film.

5. A method of manufacturing a non-volatile semiconductor memory device, comprising the steps of:
forming a plurality of element regions and an element isolation region in a semiconductor substrate, the plurality of element regions being extended in a first direction and arranged in parallel, the element isolation region isolating the element regions from each other and being filled with a first insulating film;
forming a plurality of memory cell gate electrodes on the element regions, the plurality of memory cell gate electrodes being extended in a second direction and arranged in parallel, the second direction being orthogonal to the first direction;
forming two selection gate electrodes on the element regions, the two selection gate electrodes being extended in the second direction and arranged adjacent to each other in parallel;
etching the first insulating film in such a manner that the first insulating film remains at least under the selection gate electrodes, after forming the memory cell gate electrodes and selection gate electrodes;
forming a second insulating film on the selection gate electrodes and under the selection gate electrodes in the element isolation region, the second insulating film having an etching rate in a first etching solution lower than that of the first insulating film;
forming a third insulating film on the memory cell gate electrodes in such a manner that air gaps are formed between the memory cell gate electrodes; and
forming a contact electrode between the two selection gate electrodes.

6. The method of manufacturing a non-volatile semiconductor memory device according to claim 5, wherein when the first insulating film is etched, air gaps are formed under the memory cell gate electrodes penetrating to the first direction.

7. The method of manufacturing a non-volatile semiconductor memory device according to claim 5, wherein
the first etching solution is the etching solution; and
the etching rate of the second insulating film in the first etching solution is not higher than 1/10 of that of the first insulating film in the first etching solution.

8. The method of manufacturing a non-volatile semiconductor memory device according to claim 5, wherein the second insulating film has better step coverage than the third insulating film.

9. The method of manufacturing a non-volatile semiconductor memory device according to claim 5, wherein before the step of etching the first insulating film, ion implantation is performed using the memory cell gate electrodes and the selection gate electrodes as a mask.

10. A non-volatile semiconductor memory device, comprising:
a semiconductor substrate;
an element isolation region which is formed in the semiconductor substrate, is extended in a first direction, and separates the semiconductor substrate into element regions;
a plurality of memory cell transistors arranged on the element regions;
two selection gate transistors arranged on the element regions;
a first insulating film formed under the selection gate transistors;
a second insulating film arranged on a side surface of the first insulating film on a side toward a direction that selection gate electrodes face each other;
a third insulating film arranged on the memory cell transistors;
a fourth insulating film in contact with the selection gate transistors and a side surface of the second insulating film; and
a contact electrode arranged between the selection gate transistors.

11. The non-volatile semiconductor memory device according to claim 10, wherein the element isolation region has an air gap.

12. The non-volatile semiconductor memory device according to claim 11, wherein a side surface of the first insulating film on a side opposite to the direction that the selection gate electrodes face each other is in contact with the air gap.

13. The non-volatile semiconductor memory device according to claim 10, wherein the lowest portion of the fourth insulating film is located below a lower surface of the contact electrode.

14. The non-volatile semiconductor memory device according to claim 10, further comprising a fifth insulating film filling the portion between the selection gate transistors, wherein
the lowest part of the fifth insulating film is located below a lower surface of the contact electrode.
